(19) United States
(12) Patent Application Publication
(10) Pub. No.: US 2010/0327851 A1
(43) Pub. Date: Dec. 30, 2010

(54) CONTACT MECHANISM, CARD DETECTING APPARATUS, AND CARD DETECTING METHOD

(75) Inventor: Koki TAKAHASHI, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kawasaki (JP)

(21) Appl. No.: 12/785,293

(22) Filed: May 21, 2010

(30) Foreign Application Priority Data
Jun. 30, 2009 (JP) 2009-156075

(51) Int. Cl. G01R 1/20; H01R 4/48

(52) U.S. Cl. 324/126; 439/816

(57) ABSTRACT

A contact mechanism includes a movable contact unit to be positionally changed in accordance with insertion of a detachable member; and a fixed contact pair to include a first fixed contact unit and a second fixed contact unit, the positionally changed movable contact unit coming into slidable contact with the first fixed contact unit and the second fixed contact unit to make the first fixed contact unit and the second fixed contact unit conductive through the movable contact unit.

### CROSS-REFERENCE TO RELATED APPLICATIONS

This application is based upon and claims the benefit of priority of the prior Japanese Patent Application No. 2009-156075, filed on Jun. 30, 2009, the entire contents of which are incorporated herein by reference.

### FIELD

The embodiments discussed herein are related to a contact mechanism that detects a state of engagement or attachment and detachment of a detachable member and, for example, related to a contact mechanism, a card detecting apparatus and a card detecting method for making a movable contact displaced in accordance with insertion of a card etc. contact with a fixed contact to detect the conduction state thereof.

### BACKGROUND

Conventionally, for a detachable memory card used as a recording means of an electronic device such as a portable telephone and a camera, a means of detecting the presence of the card in the device may move a contact terminal in accordance with insertion of a card to detect the conduction due to the contact between this contact terminal and a terminal on the detection side.

For such card detection, it is known to have a movable contact and a fixed contact and include a resin actuator to operate the movable contact with an inserted card to make conduction with the fixed contact (Japanese Laid-Open Patent Publication No. 2004-185822) and to have a switch consisting of a moving contact segment and a fixed contact segment in contact with the moving contact segment during a standby to open the switch by separating the moving contact segment from the fixed contact segment by an operation element when sliding a cover (Japanese Laid-Open Patent Publication No. 2008-234881).

It is also known to contact an actuator and a detection contact unit by a repulsive force to make up a switch for card detection by inserting a card into a deepest portion of an insertion opening (Japanese Laid-Open Patent Publication No. 11-097110), to displace and contact a movable contact with a mating contact by moving a sliding member with a card insertion and to providing a sliding contact unit and an abutting contact unit on the movable contact and the mating contact (Japanese Laid-Open Patent Publication No. 2007-242269), and to displace and bring a first switch terminal into contact or non-contact with a second switch terminal by insertion of a card to detect the card (Japanese Laid-Open Patent Publication No. 2006-107971).

Although engagement is determined by the conduction detection through the contact of a contact terminal on the moving side and a contact terminal on the detecting side in accordance with insertion of a card in the above card detection, a contact failure may occur due to dust attached to a contact unit of a contact terminal or an effect of a sealing treatment agent, etc. of electronic devices, for example.

Although a technique exits that slides terminals relative to each other to avoid such a contact failure, the sliding amount is small in a conventional contact terminal and it is difficult to acquire sufficient wiping effect. For example, if a convex portion coming into contact with an inserted card is enlarged in the contact terminal on the moving side to ensure a larger sliding amount, the sliding contact terminal on the fixed side needs also to be enlarged and a card connector of an electronic device, etc. needs to be enlarged as a whole. Additionally, the implementation in an electronic device, etc. becomes difficult due to increase in a resistance force against the card insertion direction.

Such requests and problems are not disclosed or suggested and the solving configuration thereof, etc. is not disclosed or suggested in Japanese Laid-Open Patent Publications Nos. 2004-185822, 2008-234881, 11-097110, 2007-242269 and 2006-107971.

### SUMMARY

According to an aspect of the disclosure, a contact mechanism detects a detachable member and includes a movable contact unit and a fixed contact pair. The movable contact unit is positionally changed in accordance with the insertion of the detachable member. The fixed contact pair has a first fixed contact unit and a second fixed contact unit and the positionally changed movable contact unit comes into slidable contact with the first fixed contact unit and the second fixed contact unit to make the first fixed contact unit and the second fixed contact unit conductive through the movable contact unit.

According to another aspect of the disclosure, a card detecting apparatus detects attachment and detachment of a card and includes a movable contact unit and a fixed contact pair. The movable contact unit is positionally changed in accordance with the insertion of the detachable card. The fixed contact pair has a first fixed contact unit and a second fixed contact unit and the positionally changed movable contact unit comes into slidable contact with the first fixed contact unit and the second fixed contact unit to make the first fixed contact unit and the second fixed contact unit conductive through the movable contact unit when the card is inserted. The card is configured to be detected through the conduction of the fixed contact pair.

According to further another aspect of the disclosure, a card detecting method detects attachment and detachment of a card and includes causing slidable movement and contact, and detecting conduction. At the causing slidable movement and contact, the slidable movement of a movable contact unit with and contact between a first fixed contact unit and a second fixed contact unit is caused by positionally changing the movable contact unit in accordance with insertion of a detachable card. At the detecting conduction, the conduction between the movable contact unit, and the first fixed contact unit and the second fixed contact unit is conducted.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

Other objects, features and advantages of the present invention will become more apparent by reference to the accompanying drawings and embodiments.

### BRIEF DESCRIPTION OF DRAWINGS

FIG. 1 is a diagram of an example of a card detecting apparatus according to a first embodiment;

FIG. 2 is a side view of the card detecting apparatus depicted in FIG. 1;

FIG. 3 is a diagram of an exemplary configuration of a movable contact piece;

FIG. 4 is a diagram of an example of a contact state of the movable contact piece and fixed contact pieces;

FIG. 5 is a perspective view of an exemplary configuration of the movable contact piece disposed on a slider;

FIG. 6 is a front view of an exemplary configuration of the movable contact piece disposed on a slider;

FIG. 7 is a diagram of an example of a state of a positional change of a contact unit of the movable contact piece;

FIG. 8 is a diagram of an example of a state at the time of partial insertion of a card;

FIG. 9 is a diagram of a state of a contact pressed and positionally changed by the card;

FIG. 10 is a diagram of a state of a tip of the card inserted until coming into contact with the slider;

FIG. 11 is a diagram of a state of the card inserted into the deepest part of a connector;

FIG. 12 is a diagram of a sliding state due to the positional change of the contact;

FIGS. 13A and 13B are diagrams of an example of a sliding state of the contact moved in the card insertion direction;

FIG. 14 is a diagram of an exemplary configuration of a groove of a heart cam mechanism according to a second embodiment;

FIG. 15 is a schematic diagram of an exemplary configuration of steps of the heart cam mechanism;

FIG. 16 is a diagram of an exemplary configuration of a card detecting apparatus according to a third embodiment;

FIG. 17 is a diagram of an example of a card detection state at the time of the card insertion;

FIG. 18 is a diagram of a sliding state due to a positional change of the movable contact piece;

FIG. 19 is a diagram of a comparative example when a sliding distance is smaller relative to the positional change of the movable contact piece; and

FIG. 20 is a diagram of a comparative example when a contacting unit of the movable contact piece is enlarged.

### DESCRIPTION OF EMBODIMENTS

To solve the above problems, according to a contact mechanism, a card detecting apparatus and a card detecting method of the disclosure, a movable contact unit is positionally changed by an inserted detachable member and is brought into contact with a fixed contact pair while sliding due to the positional change of the movable contact unit. The contacted movable contact unit brings the fixed contact pair into the conduction state.

### First Embodiment

A first embodiment is an example of a contact mechanism, a card detecting apparatus and a card detecting method and describes an exemplary configuration of disposing a movable contact unit on a slider so as to be positionally changed by insertion of a card.

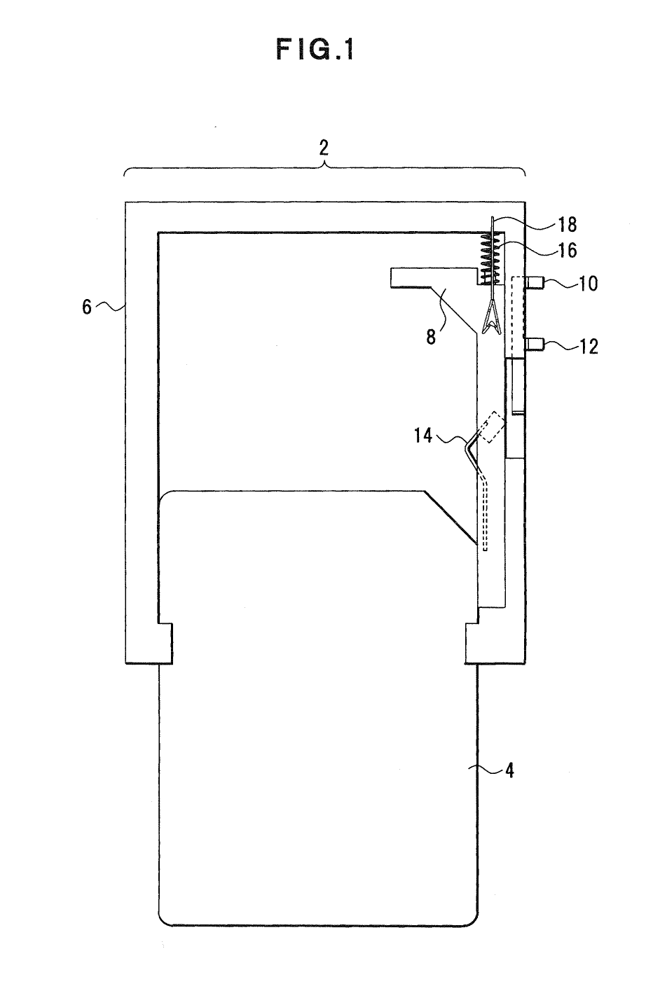

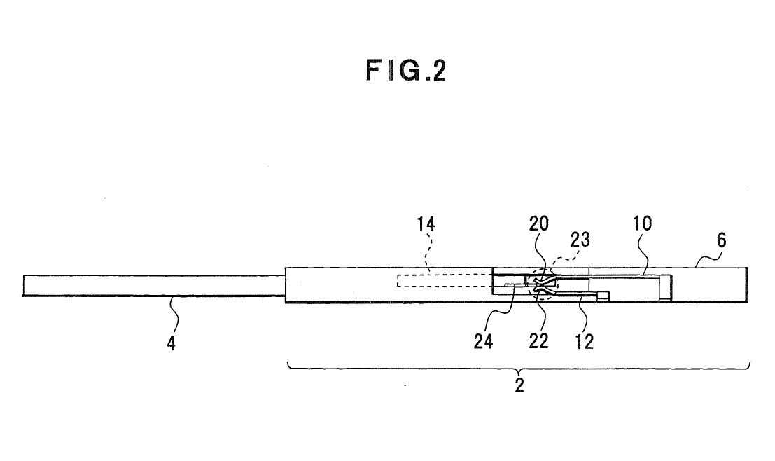

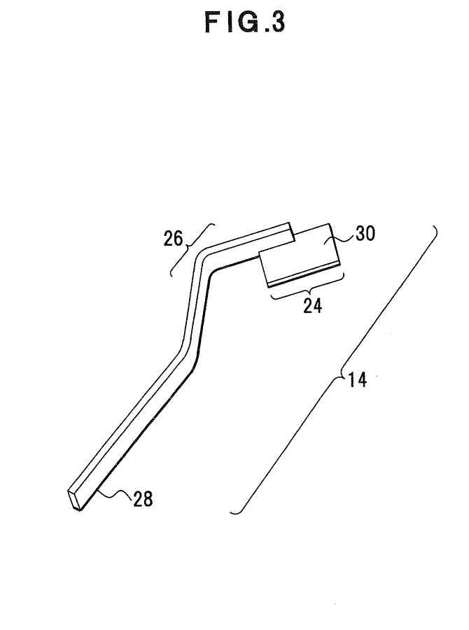

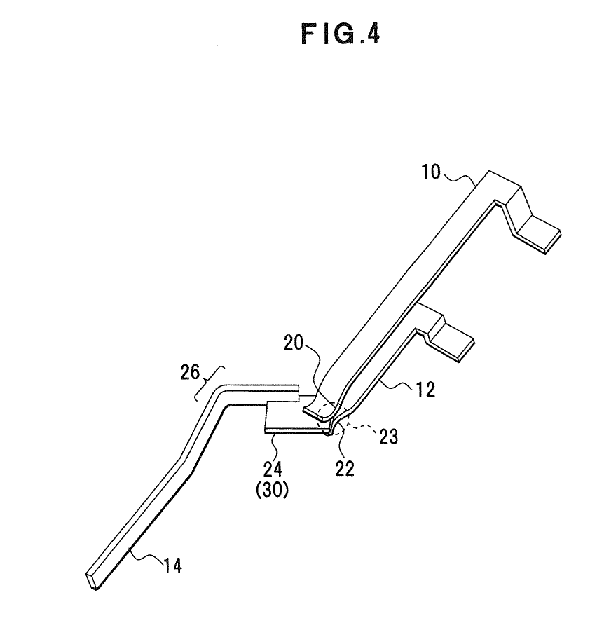

The first embodiment will be described with reference to FIGS. 1, 2, 3 and 4. FIG. 1 depicts an example of a card detecting apparatus according to a first embodiment; FIG. 2 is a side view of the card detecting apparatus depicted in FIG. 1; FIG. 3 depicts an exemplary configuration of a movable contact piece; and FIG. 4 depicts an example of a contact state of the movable contact piece and fixed contact pieces. The configurations and arrangements depicted in FIGS. 1, 2, 3 and 4 are by way of example and not limitation.

A connector 2 is an example of a contact mechanism, a card detecting apparatus and a card detecting method for detecting engagement due to insertion or attachment and detachment of a card 4, etc. for a memory that is an example of a detachable member and is, for example, an apparatus that holds the card 4 that is an insertable or detachable recording medium at a predetermined position to read or write data, etc. As depicted in FIG. 1, for example, the connector 2 includes a housing 6, a slider 8, a contact (A) 10, a contact (B) 12, a contact (C) 14, etc. When the card 4 in inserted, the contact 14 comes in contact with the contact 10 and the contact 12. This brings the contact 10 and the contact 12 into the conduction state and enables the detection of the presence of the card.

The housing 6 is an example of a holding means that holds the card 4 to be inserted and prevents the card 4 from unintentionally falling off from the connector 2, for example. The housing 6 makes up a housing unit that includes the slider 8 described later, a card detecting means that detects the presence of the card 4 in the connector 2. The housing 6 is formed by molding, etc. of an electrically insulating resin member, for example. This prevents the contacts 10 and 12 detecting insertion or attachment and detachment and the inserted card 4 from being unnecessarily brought into the conduction state.

The slider 8 is an example of a positioning means of the card 4 inserted into the connector 2 or an ejecting means that ejects the card 4 from the connector 2 and moves in accordance with the insertion of the card 4. The slider 8 is disposed inside the housing 6 and contacts with, for example, a side surface and a portion of the front surface of the inserted card 4 to position a terminal formed on the card 4 relative to a terminal unit of an electronic device, etc. not depicted. This causes a reading or writing process of data, etc. to be executed between the electronic device and the card 4. In the ejecting process of the card 4, the slider 8 guides the card 4 to the ejecting position of the housing 6. The slider 8 includes a spring 16, a pin 18, etc., and performs the positioning and ejecting operations through the extension and contraction of the spring 16 connected to the housing 6.

The contact 10 and the contact 12 represent an example of fixed contact pieces including first and second fixed contact units and make up a fixed contact pair. For example, the contact 10 and the contact 12 may be made of conductive metal, etc., and are arranged on the side surface in the housing 6. Each of the contacts 10 and 12 has one end projected out of the housing 6 and is connected to a card detecting means on a substrate of an electronic device, etc. not depicted, for example. The contacts 10 and 12 are arranged facing each other, for example, and contact units 20 and 22 coming into contact with the contact 14 described later are formed at one ends as depicted in FIG. 2. The contact units 20 and 22 are located closer to and faced to each other at a predetermined distance to make up a facing unit 23. The distance of the facing unit 23 is set such that the inserted contact 14 is held between and overlapped with the contact 10 and the contact 12 as described later and is set shorter than the thickness of the contact unit 24 (FIG. 3) of the inserted contact 14, for example. Although the facing unit 23 is formed by locating the portions of the contact 10 and the contact 12 closer in this embodiment, the facing unit 23 may be formed by the whole of the contact 10 and the contact 12. The contact 10 and the contact 12 may be made up of, for example, plate springs as a configuration capable of holding the contact 14 therebetween.

The contact 14 is an example of a movable contact piece including a movable contact unit of a card detecting apparatus, etc. and may be made of conductive metal, etc. As depicted in FIG. 3, the contact 14 includes a contact unit 24 to be contact with the contacts 10 and 12 on one end, a contacting unit 26 to be contact with the inserted card 4, and an end portion 28 on the other end. For example, as depicted in FIG. 1, the contact 14 is disposed within the slider 8 and is fixed to the slider 8 on the side of the end portion 28. The contacting unit 26 has a convex portion formed by deforming a portion of the movable contact piece, for example, and the contacting unit 26 comes into contact with the inserted card 4 and is pressed by the card 4.

The contact unit 24 of the contact 14 includes a planar portion 30 to be contact with the contacts 10 and 12. The width of the planar portion 30 of the contact unit 24 is configured wider than the contacting unit 26 in the planar direction (direction depicted in FIG. 1), for example. In the height direction, the thickness of the contact unit 24 is configured thinner than the contacting unit 26, for example. As depicted in FIG. 4, in the card detection through the contact between the movable contacting unit and the fixed contact pair, the contact unit 24 of the contact 14 is inserted into the facing unit 23 of the contacts 10 and 12 and is held between and overlapped with the contact units 20 and 22. This achieves conduction between the contact 10 and the contact 12 through the contact 14 and the insertion or attachment and detachment of the card 4 is detected.

The contact unit 24 of the contact 14 may integrally be formed with the contact 14 or a planar separate member may be disposed as the planar portion 30 of the contact 14.

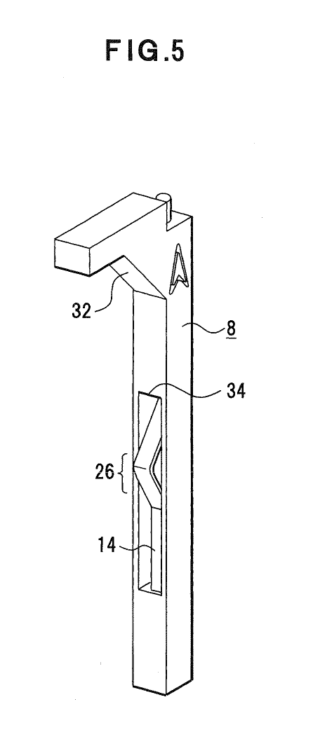

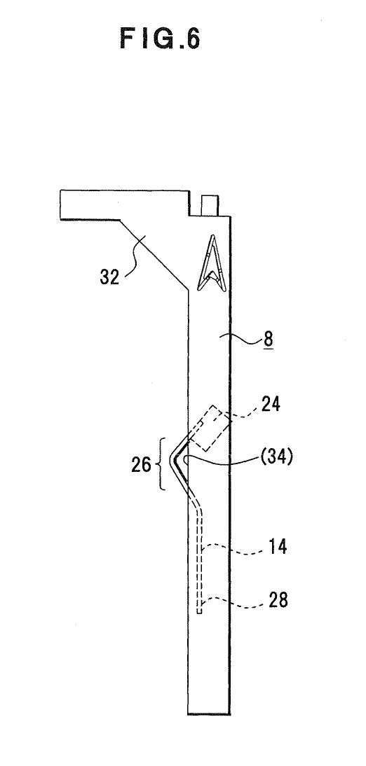

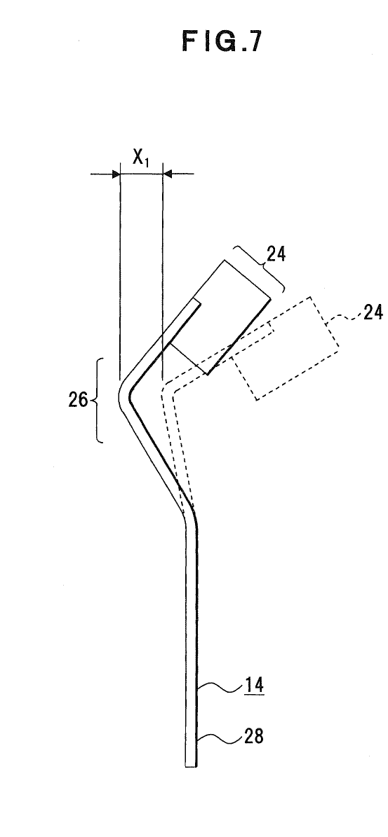

The movable contact unit configured in the slider will be described with FIGS. 5, 6 and 7. FIG. 5 is a perspective view of an exemplary configuration of the movable contact piece disposed on the slider; FIG. 6 is a front view of an exemplary configuration of the movable contact piece disposed on the slider; and FIG. 7 depicts an example of a state of a positional change of the contact unit of the movable contact piece. The configurations depicted in FIGS. 5, 6 and 7 are by way of example and not limitation.

The slider 8 is formed in an L-shape, for example, and a slope face portion 32 is formed inside the intersecting point of two sides of the L-shape to abut on a cut out portion of the inserted card 4. A window 34 is formed in the slider 8 and the contacting unit 26 of the contact 14 is disposed in the window 34 as depicted in FIG. 5. The contacting unit 26 is projected from the window 34 as depicted in FIG. 6 and when the card 4 is inserted along the slider 8, the card 4 comes into contact with the contacting unit 26 and the contact 14 is pressed.

The end portion 28 of the contact 14 is a disposing portion disposed on the slider 8 and is fixed such that the contact 14 is not displaced from the slider 8 over the pressing from the card 4. With such a configuration, the contacting unit 26 of the contact 14 disposed in the slider 8 is positionally changed by X₁ due to the pressing from the card 4 as depicted in FIG. 7 and the contact unit 24 is displaced in accordance with the positional change of the contacting unit 26.

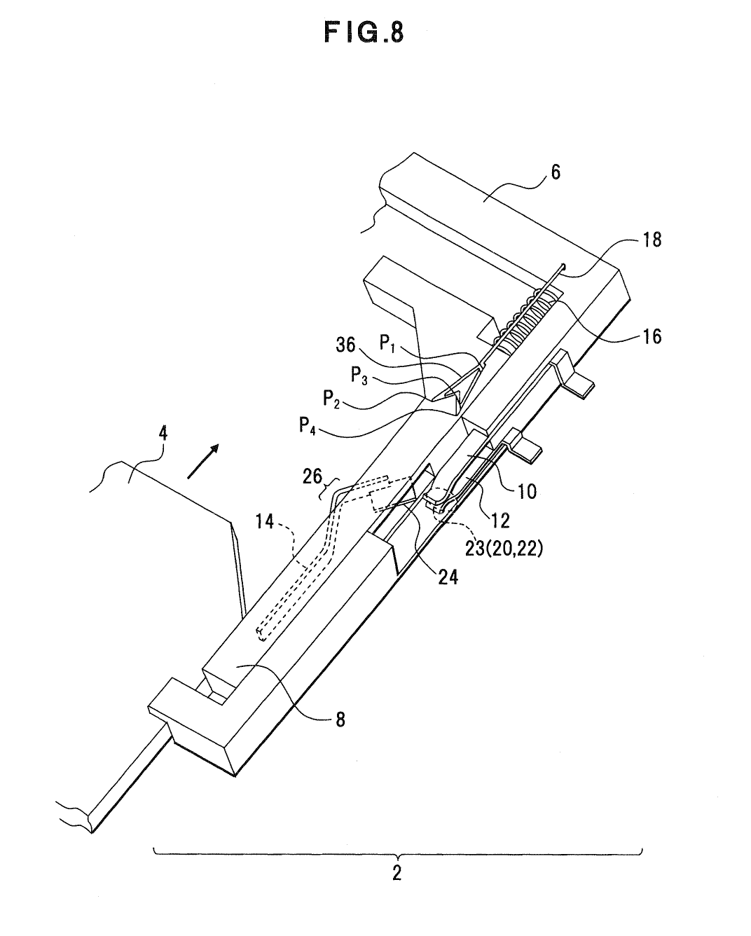

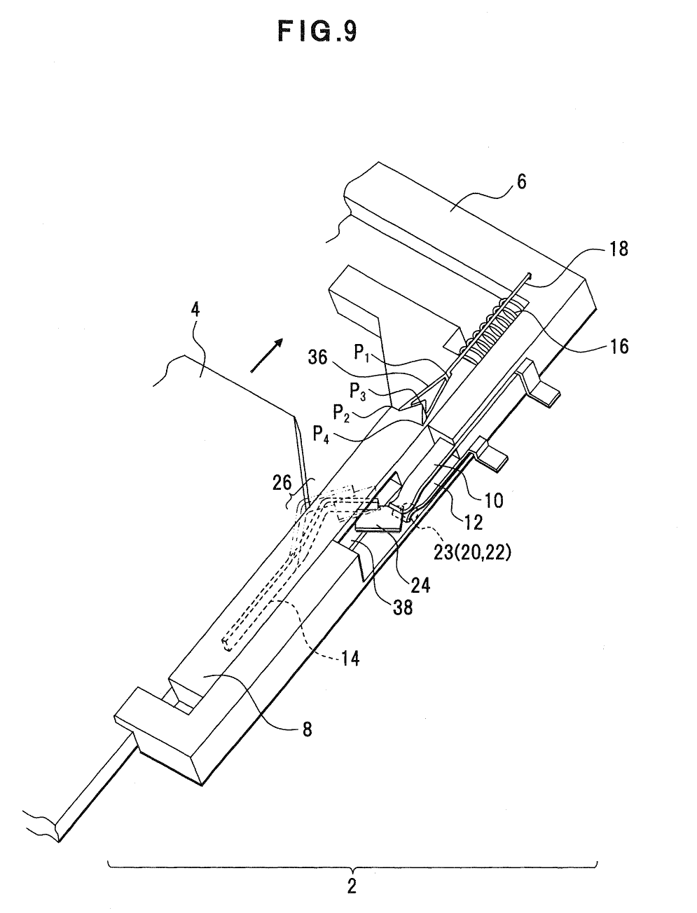

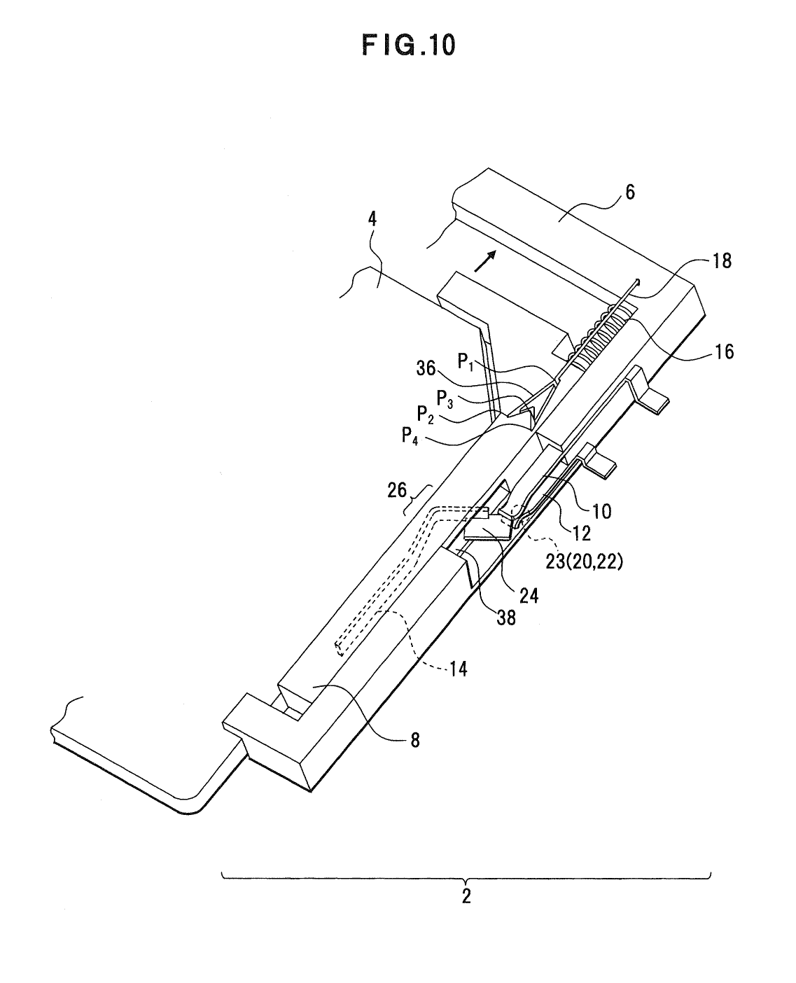

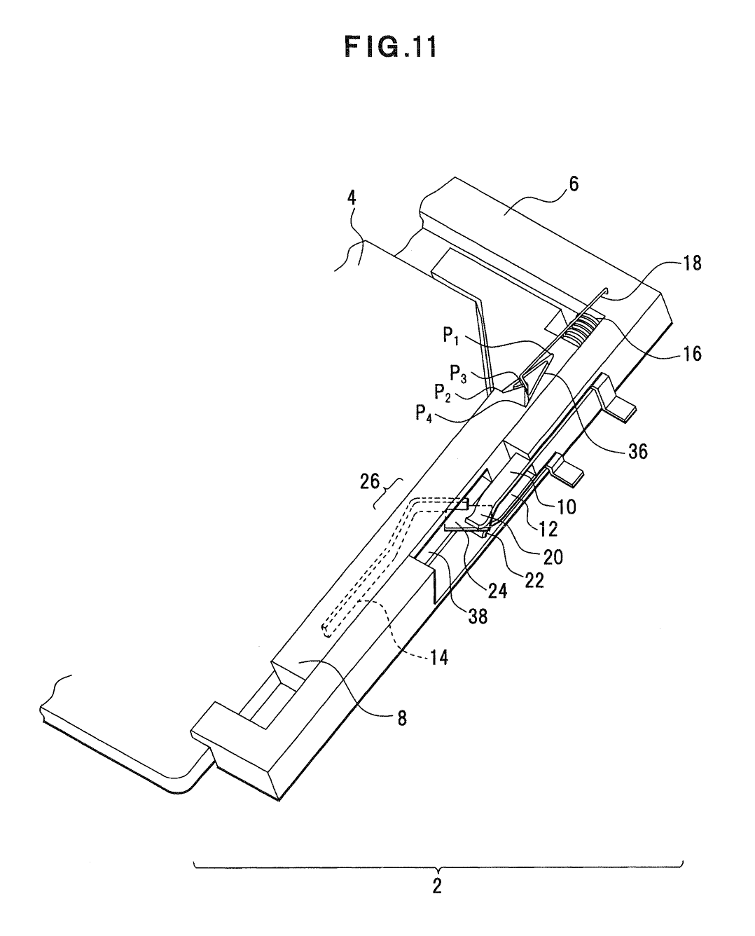

States of the slider and the movable contact piece in the connector in the card detection will be described with reference to FIGS. 8, 9, 10 and 11. FIG. 8 depicts an example of a state at the time of partial insertion of a card; FIG. 9 depicts a state of a contact pressed and positionally changed by the card; FIG. 10 depicts a state of a tip of the card inserted until coming into contact with the slider; and FIG. 11 depicts a state of the card inserted into the deepest part of the connector. The configurations depicted in FIGS. 8, 9, 10 and 11 are by way of example and not limitation.

An exemplary arrangement configuration of the slider 8, the pin 18, the spring 16, etc. will first be described.

The slider 8 performs backward and forward slide operations relative to the insertion direction of the card 4 to achieve the positioning, the ejecting process, etc. of the inserted card 4. As depicted in FIG. 8, one end of the pin 18 is connected to the top surface of the slider 8 and the other end is disposed on the housing 6 at the abutting position in the insertion direction of the card 4. The spring 16 is disposed to be sandwiched between the front surface of the slider 8 and the housing 6 along the pin 18. The pin 18 and the spring 16 represent an example of a biasing means for the slider 8 and apply a reaction force to the movement of the slider 8 due to the insertion of the card 4.

The slider 8 includes a groove 36 using a heart cam mechanism as a positioning means utilizing the reaction force from the pin 18 and the spring 16. The tip of the pin 18 disposed on the slider 8 is engaged with the groove 36 and the tip of the pin 18 moves within the groove 36 in accordance with the movement of the slider 8 due to the insertion of the card 4. The groove 36 includes, for example, P₁, P₂, P₃ and P₄ set as vertices formed by the heart cam mechanism. The vertices P₁, P₂, P₃ and P₄ set within the groove 36 may be provided with a reverse movement preventing means such as steps, for example.

A relationship between the movement of the slider 8 and the movement of the pin 18 in the groove 36 will be described in such a configuration. As depicted in FIG. 8, while the card 4 is partially inserted into the connector 2 or not inserted, if the slider 8 is not moved, the spring 16 has the longest length and the tip of the pin 18 is located at the vertex P₁ of the groove 36. If the slider 8 is pushed in by the insertion of the card 4 as depicted in FIGS. 9 and 10, the spring 16 is compressed along the pin 18 by the advance of the slider 8 as depicted in FIG. 11. In this case, the length of the pin 18 is not changed and the tip of the pin 18 moves along the groove 36. The displacement amount of the tip of the pin 18 from the vertex P₁ to the vertex P₂ corresponds to the movement amount of the slider 8 due to the insertion of the card 4 and the arrival of the pin 18 at the vertex P₂ indicates that the slider 8 is pushed into the maximum insertion position of the connector 2.

When arriving at the vertex P₂ of the groove 36, the pin 18 is not fixed at the position thereof and guided toward the vertex P₃ due to the reaction force of the spring 16. That is, the slider 8 and the card 4 are pushed back toward the insertion opening of the connector 2 due to the movement from the vertex P₂ to vertex P₃. The groove 36 is formed in an inverted V-shape, for example, and since the tip of the pin 18 is retained against the reaction force of the spring 16 at the vertex P₃, the insertion position of the slider 8 and the card 4 is fixed.

The card 4 is ejected by utilizing a so-called push-on/push-off type of alternate operation, for example, and when the card 4 is pushed again in the insertion direction of the connector 2, the pin 18 goes back from the vertex P₃ through the vertex P₄ to the vertex P₁. Since this restores the original length of the spring 16 and the slider 8 goes back to the position at the time of non-insertion of the card, the ejecting process of the card 4 is executed.

The card detecting method will then be described.

In this card detecting method, the pressing from the inserted card 4 positionally changes the contact unit 24 of the contact 14 that is a movable contact piece and the contact unit 24 is sandwiched by the contacts 10 and 12, which are fixed contact pieces, to make slidable contact therewith. The contact 14 disposed on the slider 8 moves in the insertion direction of the card 4 while being sandwiched by and in contact with the contacts 10 and 12. The card 4 is detected since the contacts 10 and 12 are brought into the conduction state through the contact 14. At this time, the contact unit 24 of the contact 14 slides between the contact 10 and the contact 12 in accordance with the positional change due to the pressing and the positional change due to the movement of the slider 8.

In the state of the card 4 not inserted into a predetermined position of the connector 2 or the non-insertion state of the card, the card 4 does not contact with the contacting unit 26 of the contact 14 as depicted in FIG. 8, and the contact unit 24 is located within the slider 8. Therefore, the contact 14 does not contact and is not made conductive with the contact 10 and the contact 12 and, for example, a card detecting/determining means not shown determines that the card 4 is not inserted.

When the card 4 is inserted to the position of the contacting unit 26 of the contact 14, i.e., the predetermined position of the connector 2, the contact 14 is pressed by the card 4 as depicted in FIG. 9. As a result, the contact unit 24 of the contact 14 is displaced and projected from the window 38 disposed in the slider 8. Due to this displacement, the contact unit 24 of the contact 14 is sandwiched by and comes into contact with the contact units 20 and 22 of the contacts 10 and 12 and the conduction state is achieved.

When the card 4 is further inserted into the connector 2, the leading end of the card 4 contacts with the slider 8 as depicted in FIG. 10. As depicted in FIG. 11, the contact 14 is positionally changed in the card insertion direction along with the slider 8 by the insertion of the card 4. Due to this position change, the contact unit 24 of the contact 14 slides relative to the contact units 20 and 22 of the contacts 10 and 12 being in contact.

When the card 4 is pushed into the deepest part of the connector 2, the pin 18 moves to the vertex P₂ of the groove 36 and the movement of the slider 8 is limited in the insertion direction. When the pushing of the card 4 is released, the pin 18 moves to the vertex P₃ of the groove 36 and the card 4 is fixed. The contact unit 24 of the contact 14 is being sandwiched between the contact points 20 and 22 at this point and the contact 10 and the contact 12 are in the conduction state.

At the time of ejection of the card 4, as described above, when the card 4 is pushed in again in the insertion direction, the contact 14 is pushed in along with the slider 8. In this operation, the contact unit 24 of the contact 14 also slides relative to the contact units 20 and 22 of the contacts 10 and 12 being in contact. When the slider 8 goes back to the initial position (FIG. 8), the contact unit 24 of the contact 14 slides and moves between the contact units 20 and 22 of the contacts 10 and 12 in the direction opposite to the card insertion direction. When the card 4 is ejected to the predetermined position (FIG. 8) of the connector 2, the pressing to the contact 14 by the card 4 is released. This cancels the conduction state between the contact 10 and the contact 12 and the above card detecting apparatus determines that the card 4 is in the non-inserted state.

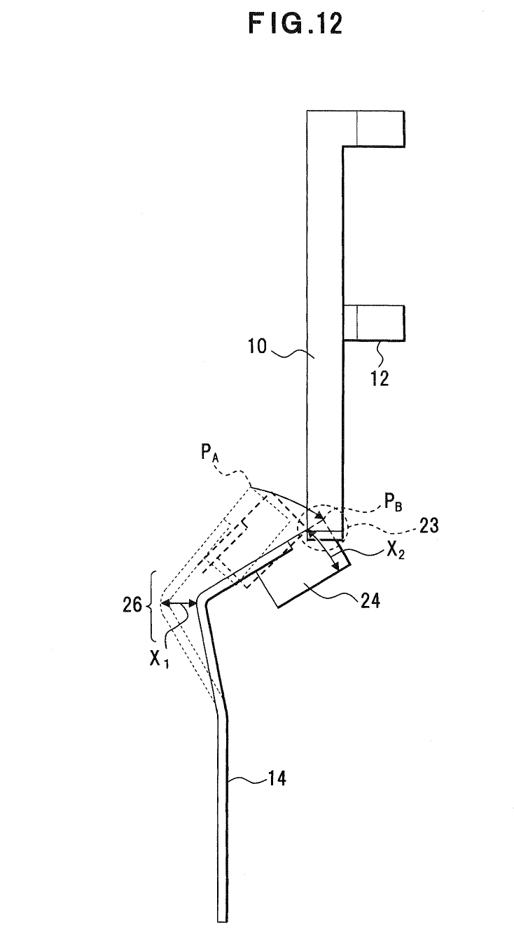

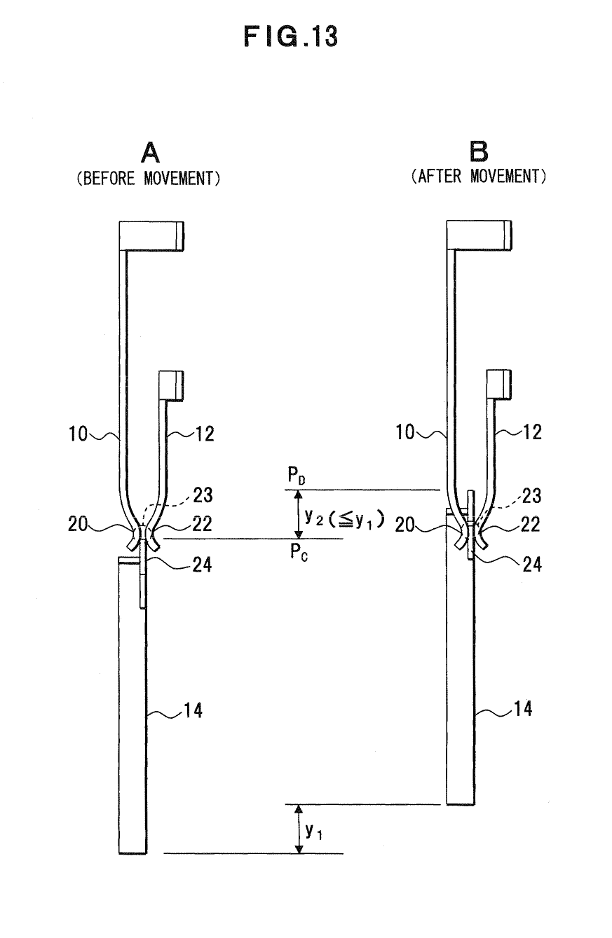

The sliding between the contacts 10 and 12 and the contact 14 will be described with reference to FIGS. 12 and 13. FIG. 12 depicts a sliding state due to the positional change of the contact and FIGS. 13A and 13B depict a sliding state of the contact moved in the card insertion direction. The configurations depicted in FIGS. 12 and 13 are by way of example and not limitation.

Description will first be made of the sliding in accordance with the positional change of the contact 14 due to the pressing of the card 4. The contact 14 is positionally changed by being pressed due to the insertion of the card 4 as above. As depicted in FIG. 12, for example, if the contacting unit 26 is displaced by, for example, X₁ due to the pressing, the contact unit 24 is positionally changed from position P_{A} to P_{B}. Due to this positional change, the contact unit 24 is interposed into the facing unit 23 of the contact 10 and the contact 12 and slides for a distance X₂, for example. The sliding distance X₂ depicted in FIG. 12 illustrates an example at an arbitrary point of the contact unit 24 and the sliding distance varies depending on the position of contact with the contact 10 and the contact 12.

The sliding due to movement in the card insertion direction will be described. FIG. 13A depicts a state before the movement of the contact 14. A portion of the contact unit 24 of the contact 14 is in contact with the contacts 10 and 12 in accordance with the positional change of the contact unit 24 due to the insertion of the card 4 at this timing. FIG. 13B depicts a state of the contact 14 moved by a distance y₁ with the contact potion 24 held by the facing unit 23 between and overlapped with the contact unit 20 of the contact 10 and the contact unit 22 of the contact 12. In FIGS. 13A and 13B, P_{c} denotes a position of the start of the contact of the contact unit 24 with the contact units 20 and 22 and P_{D} denotes a position of the position P_{c} on the contact unit 24 after the movement in the card insertion direction.

Since the contact unit 24 of the contact 14 is in contact with the contacts 10 and 12 before movement as described above, the sliding distance y₂ corresponds to the movement distance y₁ of the contact unit 24 of the contact 14. That is, depending on the contact state of the contact 14 and the contacts 10 and 12 at the position P_{c}, the sliding distance Y₂ becomes equivalent to the movement distance y₁ or shorter than y₁.

Therefore, the contact unit 24 of the contact 14 may ensure the sliding distances of X₂ in the direction of the positional change due to the pressing and y₂ in the insertion direction of the card 4 relative to the contacts 10 and 12.

With this configuration, for the positional change and the movement of the movable contact piece due to the insertion of the card, a greater sliding distance of the contact unit of the movable contact piece may be ensured by interposing the movable contact piece between the fixed contact pieces in a facing arrangement. Even if the displacement amount of the movable contact piece is enlarged to ensure a greater sliding distance, the fixed contact pieces are not accordingly displaced and, therefore, a card detecting apparatus such as a connector may be prevented from increasing in size.

### Second Embodiment

A second embodiment relates to an exemplary configuration of a heart cam mechanism.

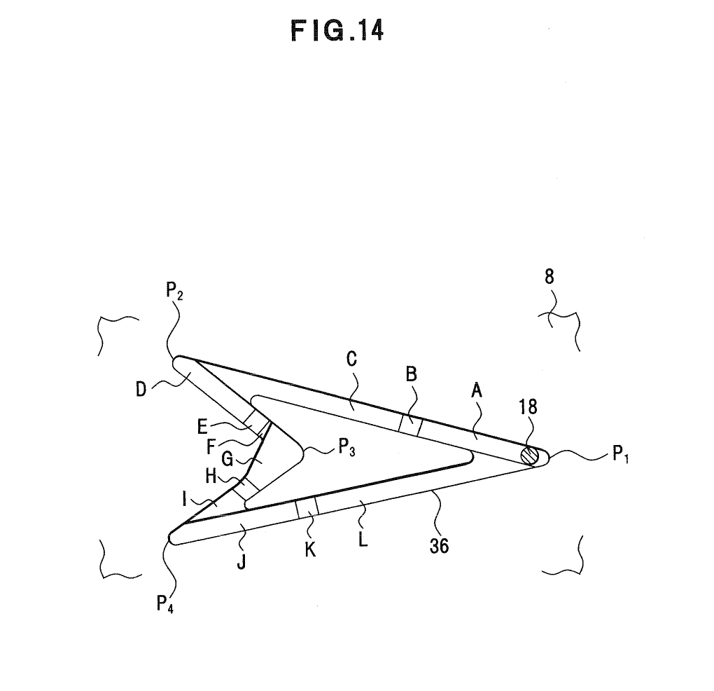

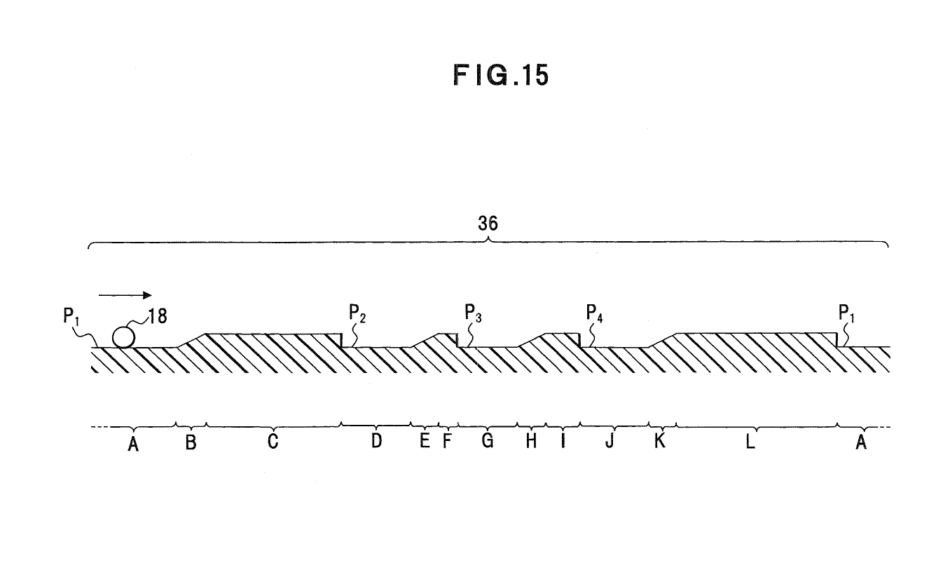

The second embodiment will be described with reference to FIGS. 14 and 15. FIG. 14 depicts an exemplary configuration of a groove of a heart cam mechanism according to the second embodiment and FIG. 15 is a schematic diagram of an exemplary configuration of steps of the heart cam mechanism. The configurations depicted in FIGS. 14 and 15 are by way of example and not limitation. In the configuration of FIG. 14, the same portions as FIGS. 8 to 11 are denoted by the same reference numerals.

As described above, the heart cam mechanism makes up the positioning means for the card 4, the ejecting means for the card 4, etc. through the movement control of the slider 8. Therefore, for example, the heart cam mechanism also acts as a movement control means for the movable contact piece included inside the slider 8 and positionally changed by the movement of the slider 8.

As depicted in FIG. 14, the vertices P₁, P₂, P₃ and P₄ are disposed within the groove 36 of the heart cam mechanism and the reverse movement preventing means for the pin 18 is disposed between these vertices P₁, P₂, P₃ and P₄ by utilizing a difference in height between steps configured at a plurality of locations, for example. Reference numerals A, B, C . . . L, of FIG. 14 denote positions having different heights as to bottom surfaces of the groove 36 and FIG. 15 depicts an example of a state of the height of the bottom surfaces from A to L of the grove 36.

On the reverse movement preventing means utilizing a difference in height between the bottom surfaces of the grove 36, as depicted in FIG. 15, for example, when moving from the point C to the point D at the vertex P₂ the pin 18 moves from the upper surface to the lower surface. Similarly, the pin 18 moves from the upper surface to the lower surface when moving from the point F to the point G at the vertex P₃, when moving from the point I to the point J at the vertex P₄, and when moving from the point L to the point A at the vertex P₁. This enables the prevention of the reverse movement of the pin 18 with the steps disposed immediately before the vertices P₁ to P₄.

Therefore, in the heart cam mechanism, when the card 4 is inserted, the pin 18 moves from the vertex P₁ through P₂ to P₃ due to the movement of the slider 8, and the contact 14, i.e., the movable contact piece is accordingly moved at the same time. Therefore, a linear distance from the vertex P₁ indicative of the no card inserted state to the vertex P₃ indicative of the inserted state of the card 4 corresponds to the movement distance y₁ of the contact 14.

With this configuration, a grater sliding distance may be ensured and the wiping effect may be enhanced as is the case with the above embodiment. Since the heart cam mechanism determines the movement path and the stopping positions of the slider and the reverse movement prevention means determines the movement and the stopping positions of the movable contact piece due to the card insertion, the accuracies of contact, sliding, etc. against the fixed contact pieces may be improved to improve the credibility of the detection accuracy of the card insertion.

### Third Embodiment

A third embodiment relates to a variation of the sliding due to the positional change of the movable contact piece.

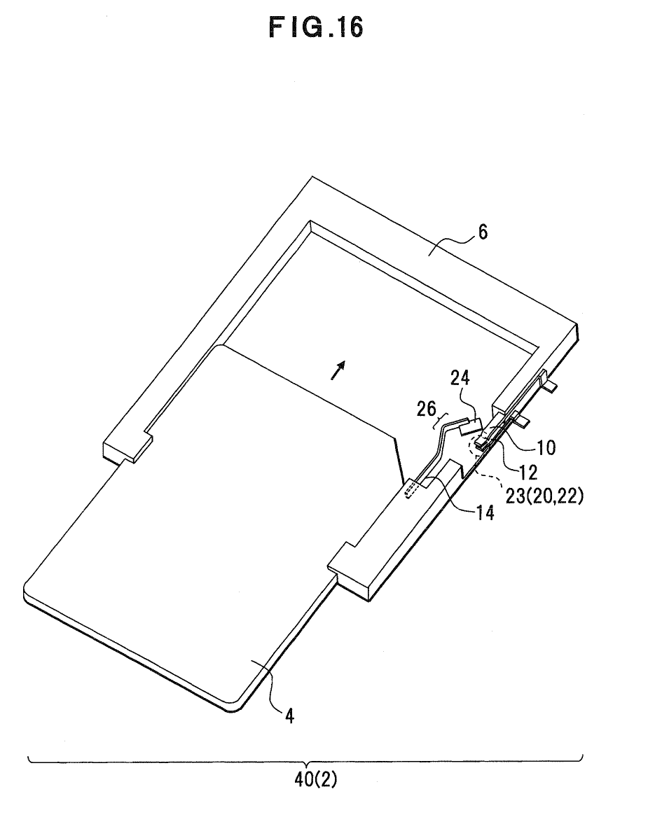

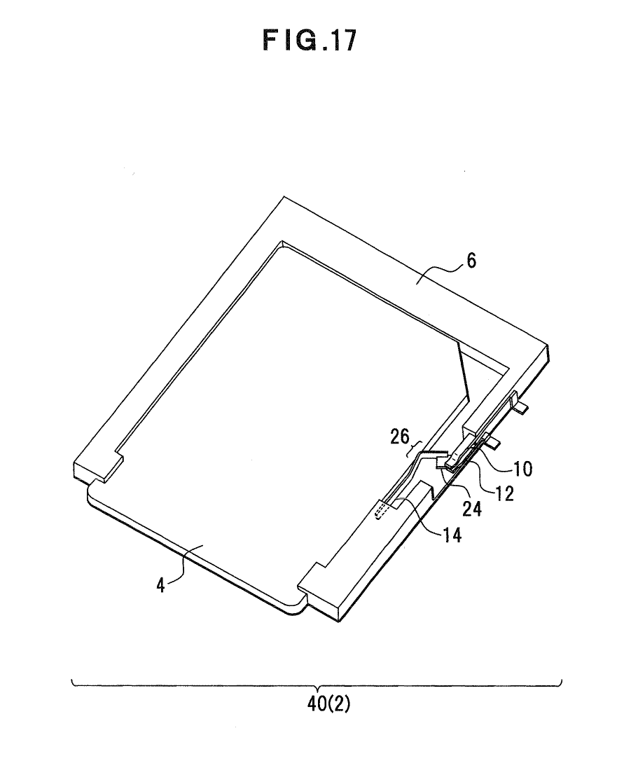

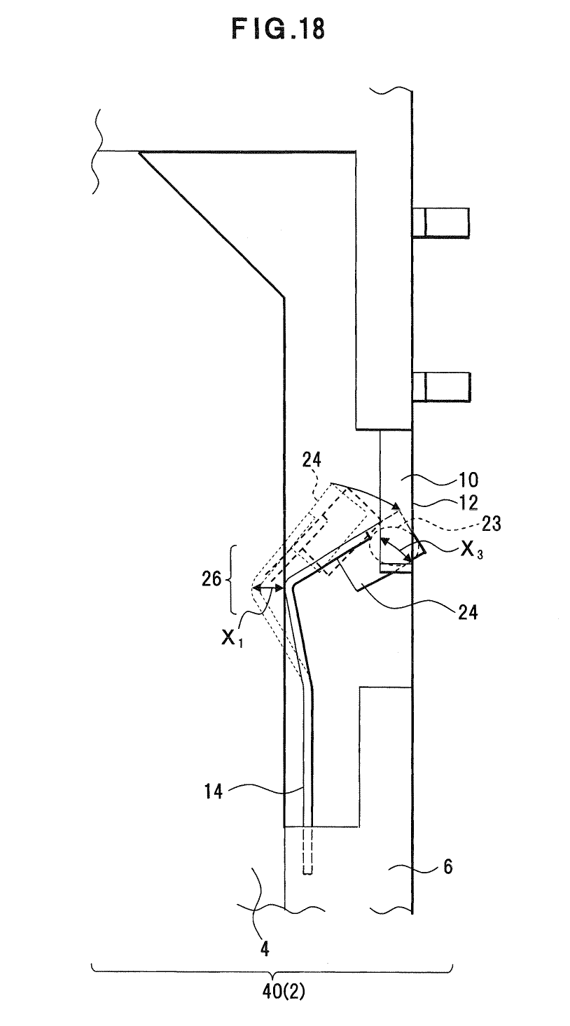

The third embodiment will be described with reference to FIGS. 16, 17 and 18. FIG. 16 depicts an exemplary configuration of a card detecting apparatus according to the third embodiment; FIG. 17 depicts an example of a card detection state at the time of the card insertion; and FIG. 18 depicts a sliding state due to a positional change of the movable contact piece. The configurations depicted in FIGS. 16, 17 and 18 are by way of example and not limitation. In FIGS. 16, 17 and 18, the same portions as FIG. 1, etc., are denoted by the same reference numerals.

A connector 40 is an example of a contact mechanism, a card detecting apparatus and a card detecting method and includes the housing 6 that is a card holding means, the contact 14 that is a movable contact piece, the contacts 10 and 12 that are first and second fixed contact units, etc., as depicted in FIG. 16.

In the connector 40, the contact 14 is disposed on the housing 6 to make up a card detecting means not moving in the card insertion direction. In this case, the contact 14 is disposed in parallel with the card 4, for example, and is fixed at one end to the housing 6 in a state of a so-called cantilever state, for example. As depicted in FIG. 17, when the card 4 is inserted into the connector 40, the contacting unit 26 formed at the center portion of the contact 14 is pressed by the card 4. This positionally changes the contact unit 24 of the contact 14 in accordance with the principle of leverage, for example.

For example, the contacts 10 and 12 are arranged facing each other at a predetermined distance as above to make up the facing unit 23 (FIG. 16). The contact unit 24 of the contact 14 is inserted into the facing unit 23 and is held between the contact units 20 and 22 of the contacts 10 and 12 to achieve the overlapping state.

As above, the contact unit 24 of the contact 14 is sandwiched between and slidably contacts with the contact unit 20 of the contact 10 and the contact unit 22 of the contact 12. In this case, as depicted in FIG. 18, for example, if the displacement amount of the contact 14 is X₁, the sliding distance at an arbitrary position of the contact unit 24 is X₃.

In comparison with the first embodiment, the connector 40 is the embodiment exemplarily illustrating a configuration not moving the contact 14 that is the movable contact piece and does not represent a configuration limiting the disposition of a slider on the connector 40. Therefore, a slider not depicted may be included as the card holding means, the positioning means and the ejecting means.

With this configuration, a greater sliding distance of the contact unit of the movable contact piece may be ensured by sandwiching and slidably contacting the movable contact piece positionally changed by the card insertion with the first and second fixed contact pieces. Since the greater sliding distance is ensured, the credibility of the card detection accuracy may be improved and the connector may be prevented from increasing in size.

### Comparative Examples

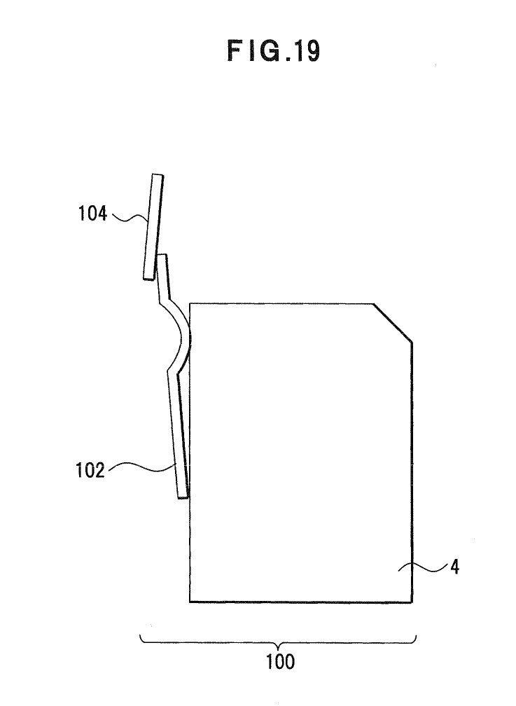

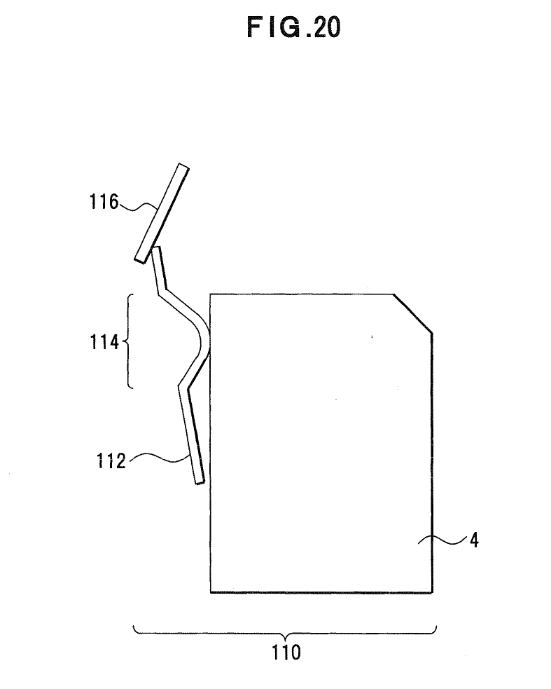

Comparative examples of the above embodiments will be described with reference to FIGS. 19 and 20. FIG. 19 depicts a comparative example when a sliding distance is smaller relative to the positional change of the movable contact piece and FIG. 20 depicts a comparative example when the contacting unit of the movable contact piece is enlarged.

A card detecting apparatus 100 depicted in this comparative example includes a movable contact piece 102 positionally changed by the card insertion and the fixed contact piece 104 for sliding in the perpendicular direction relative to the displacement direction of the movable contact piece 102, for example. With this configuration, as depicted in FIG. 19, if the displacement amount of the movable contact piece 102 in accordance with the insertion of a card 4 is small, it is difficult to acquire the sufficient wiping effect since the sliding amount is small.

A card detecting apparatus 110 depicted in FIG. 20 is configured with an enlarged convex portion that is a contacting unit 114 for the card 4 to increase the displacement amount of a movable contact piece 112. As a result, the card detecting apparatus such as a connector needs to be enlarged as a whole since a fixed contact piece 116 to be contact with needs to be disposed with an increased angle or needs to be disposed at a position distant from the card 4 in accordance with the displacement amount of the movable contact piece 114. A greater force is required for inserting the card 4. On the other hand, such inconveniences are not caused by the configurations described in the above embodiments.

### Other Embodiments

(1) Although the above embodiments are configured to make the contact 10 and the contact 12 conductive through the contact with the contact 14 positionally changed in accordance with the insertion of the card 4, this is not limitation and the conduction may be canceled by the contact with the contact 14. For example, in the connector 2 depicted in FIG. 2, the contact 10 and the contact 12, i.e., the fixed contact pieces are arranged in contact with each other and always in the conduction state if the insertion of the card 4 is not detected. That is, the distance within the facing unit 23 is set to zero. When the card 4 is inserted into the connector 2, the contact unit 24 of the contact 14, i.e., the movable contact piece is positionally changed and sandwiched and overlapped with the facing unit 23 of the contact 10 and the contact 12 as above to cancel the conduction state. In this case, for example, the contact 14 may be made of an insulating material not electrically conductive, such as a resin.

In the connector 2, the contact unit 24 of the contact 14 is sandwiched and slidably contacts with the facing unit 23 of the contacts 10 and 12. With this configuration, a greater sliding distance may be acquired without enlargement of the connector for the card. By sliding the contact 10 and the contact 12 with the contact 14 being in contact, the wiping effect may be acquired and the detection accuracy of the card insertion may be improved. Since the contact 14 in contact with the card 4 may be made of an insulating material, etc., unnecessary conduction to the card 4 may be prevented at the time of the insertion of the card as an additional effect.

(2) Although the above embodiments exemplarily illustrate the case that the sliding generated by the movement in the card insertion direction is achieved along with the sliding generated by the positional change in accordance with the pressing from the card 4 or the sliding generated by the pressing, this is not limitation and, for example, only the sliding generated by the movement in the card insertion direction may be configured to be achieved. That is, in the above configuration, the contact 14 formed on the slider 8 may be configured not to come into contact with the contacts 10 and 12 in accordance with the positional change (FIG. 10) of the contact unit 24 due to the pressing from the card 4.

With this configuration, a greater sliding distance may be acquired in accordance with the movement in the card insertion direction and the connector 2 may be prevented from increasing in size. The accuracy of the card detection may be enhanced by using two card detection conditions, which are the displacement and the movement of the contact 14.

(3) The shapes and configurations of the contact 14 and the slider 8 exemplarily illustrated in the above embodiments are not limited and, for example, the configurations may be modified depending on a type and a shape of a card to be inserted.

(4) Although the contacts 10 and 12, i.e., the first and second fixed contact pieces are described as a fixed contact pair that detects the insertion or attachment and detachment of the card 4 through the conduction state in the above embodiments, this is not limitation and a plurality of movable contact units may be included. The movable contact units may be brought into slidable contact with the fixed contact pair by insertion of a card to make the fixed contact pair conductive through the movable contact units. With this configuration, the same effect as above may be acquired.

According to the contact mechanism, the card detecting apparatus and the card detecting method of the disclosure, the following effects may be acquired.

(1) The wiping effect due to the sliding between the movable contact unit and the fixed contact pair is enhanced and the detection accuracy of the card insertion may be improved.

(2) Since the fixed contact causing the sliding is not displaced even if the positional change of the movable contact unit due to the card insertion is increased, a connector for the card or a device including the card detection function may be prevented from increasing in size.

Technical ideas extracted from the embodiments of the present invention described above will then be listed. The technical ideas according to the present invention may be comprehended at various levels and variations ranging from higher to lower conceptions and the present invention is not limited to the following description.

A contact mechanism includes a movable contact unit to be positionally changed in accordance with insertion of a detachable member; and a fixed contact pair to include a first fixed contact unit and a second fixed contact unit, the positionally changed movable contact unit coming into slidable contact with the first fixed contact unit and the second fixed contact unit to make the first fixed contact unit and the second fixed contact unit conductive through the movable contact unit.

In the above contact mechanism, preferably, the fixed contact pair may make up a facing unit with the first fixed contact unit and the second fixed contact unit faced to each other at a predetermined distance to sandwich and hold the positionally changed movable contact unit with the facing unit.

In the above contact mechanism, preferably, the first fixed contact unit and the second fixed contact unit may face to each other at a distance smaller than the thickness of the movable contact unit.

In the above contact mechanism, preferably, the movable contact unit may be disposed on a slider unit moved in accordance with the insertion of the detachable member in an insertion direction of the detachable member and be positionally changed along with the slider unit.

In the above contact mechanism, preferably, the movable contact unit may include a contacting unit pressed by contact with the inserted detachable member and is positionally changed by the pressing.

In the above contact mechanism, preferably, the movable contact unit may partially project from the slider unit due to pressing from the inserted detachable member.

A card detecting apparatus that detects attachment and detachment of a card includes a movable contact unit to be positionally changed in accordance with insertion of a detachable card; and a fixed contact pair to include a first fixed contact unit and a second fixed contact unit, the positionally changed movable contact unit coming into slidable contact with the first fixed contact unit and the second fixed contact unit to make the first fixed contact unit and the second fixed contact unit conductive through the movable contact unit when the card is inserted, wherein the card is detected through the conduction of the fixed contact pair.

In the above card detecting apparatus, preferably, the fixed contact pair may make up a facing unit with the first fixed contact unit and the second fixed contact unit faced to each other at a predetermined distance to sandwich and hold the positionally changed movable contact unit with the facing unit.

In the above card detecting apparatus, preferably, the first fixed contact unit and the second fixed contact unit may face to each other at a distance smaller than the thickness of the movable contact unit.

The above card detecting apparatus may preferably include a slider unit to be disposed with the movable contact unit inside and positionally changed in accordance with the insertion of the card in an insertion direction of the card, wherein the movable contact unit is positionally changed along with the slider unit in accordance with the insertion of the card.

In the above card detecting apparatus, preferably, the movable contact unit may include a contacting unit pressed by contact with the inserted card and is positionally changed by the pressing.

In the above card detecting apparatus, preferably, the movable contact unit may partially project from the slider unit due to pressing from the inserted card.

The above card detecting apparatus may preferably include a housing unit to hold the inserted card, wherein the fixed contact pair is disposed on the housing unit.

A card detecting method of detecting attachment and detachment of a card includes causing a movable contact unit to slidably move with and to be contacted between a first fixed contact unit and a second fixed contact unit by positionally changing the movable contact unit in accordance with insertion of a detachable card; and detecting conduction between the movable contact unit, and the first fixed contact unit and the second fixed contact unit.

The above card detecting method may preferably include interposing the positionally changed movable contact unit into a facing unit having the first fixed contact unit and the second fixed contact unit faced to each other at a predetermined distance.

The above card detecting method may preferably include moving a slider unit disposed with the movable contact unit inside in accordance with the insertion of the card in an insertion direction of the card; and positionally changing the movable contact unit along with the slider unit in accordance with the insertion of the card.

The above card detecting method may preferably include causing the movable contact unit to partially project from the slider unit due to the pressing from the inserted card.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

Although the preferred embodiments of the contact mechanism, the card detecting apparatus and the card detecting method have been described as above, the present invention is not limited to the description and may variously be modified or altered by those skilled in the art based on the spirit of the present invention described in claims or disclosed in description of embodiments of course and it is needless to say that such modifications and alterations fall within the present invention.

The contact mechanism, the card detecting apparatus and the card detecting method of this disclosure may improve the detection accuracy of an inserted card, etc. since a greater sliding distance may be acquired and the wiping effect is enhanced by bringing the movable contact unit positionally changed in accordance with the insertion of the detachable member such as a card into slidable contact with the first and second fixed contact units facing each other, which is useful.

What is claimed is:

1. A contact mechanism comprising:
a movable contact unit to be positionally changed in accordance with insertion of a detachable member; and
a fixed contact pair to include a first fixed contact unit and a second fixed contact unit, the positionally changed movable contact unit coming into slidable contact with the first fixed contact unit and the second fixed contact unit to make the first fixed contact unit and the second fixed contact unit conductive through the movable contact unit.

2. The contact mechanism of claim 1, wherein the fixed contact pair makes up a facing unit with the first fixed contact unit and the second fixed contact unit faced to each other at a predetermined distance to sandwich and hold the positionally changed movable contact unit with the facing unit.

3. The contact mechanism of claim 2, wherein the first fixed contact unit and the second fixed contact unit face to each other at a distance smaller than the thickness of the movable contact unit.

4. The contact mechanism of claim 1, wherein the movable contact unit is disposed on a slider unit moved in accordance with the insertion of the detachable member in an insertion direction of the detachable member and is positionally changed along with the slider unit.

5. The contact mechanism of claim 1, wherein the movable contact unit includes a contacting unit pressed by contact with the inserted detachable member and is positionally changed by the pressing.

6. The contact mechanism of claim 4, wherein the movable contact unit partially projects from the slider unit due to pressing from the inserted detachable member.

7. A card detecting apparatus that detects attachment and detachment of a card, comprising:
a movable contact unit to be positionally changed in accordance with insertion of a detachable card; and
a fixed contact pair to include a first fixed contact unit and a second fixed contact unit, the positionally changed movable contact unit coming into slidable contact with the first fixed contact unit and the second fixed contact unit to make the first fixed contact unit and the second fixed contact unit conductive through the movable contact unit when the card is inserted, wherein
the card is detected through the conduction of the fixed contact pair.

8. The card detecting apparatus of claim 7, wherein the fixed contact pair makes up a facing unit with the first fixed contact unit and the second fixed contact unit faced to each other at a predetermined distance to sandwich and hold the positionally changed movable contact unit with the facing unit.

9. The card detecting apparatus of claim 8, wherein the first fixed contact unit and the second fixed contact unit face to each other at a distance smaller than the thickness of the movable contact unit.

10. The card detecting apparatus of claim 7, further comprising:
a slider unit to be disposed with the movable contact unit inside and positionally changed in accordance with the insertion of the card in an insertion direction of the card, wherein
the movable contact unit is positionally changed along with the slider unit in accordance with the insertion of the card.

11. The card detecting apparatus of claim 7, wherein the movable contact unit includes a contacting unit pressed by contact with the inserted card and is positionally changed by the pressing.

12. The card detecting apparatus of claim 10, wherein the movable contact unit partially projects from the slider unit due to pressing from the inserted card.

13. The card detecting apparatus of claim 7, further comprising:
a housing unit to hold the inserted card, wherein
the fixed contact pair is disposed on the housing unit.

14. A card detecting method of detecting attachment and detachment of a card, comprising:
causing a movable contact unit to slidably move with and to be contacted between a first fixed contact unit and a second fixed contact unit by positionally changing the movable contact unit in accordance with insertion of a detachable card; and
detecting conduction between the movable contact unit, and the first fixed contact unit and the second fixed contact unit.

15. The card detecting method of claim 14, further comprising:
interposing the positionally changed movable contact unit into a facing unit having the first fixed contact unit and the second fixed contact unit faced to each other at a predetermined distance.

16. The card detecting method of claim 14, further comprising:
moving a slider unit disposed with the movable contact unit inside in accordance with the insertion of the card in an insertion direction of the card; and
positionally changing the movable contact unit along with the slider unit in accordance with the insertion of the card.

17. The card detecting method of claim 16, further comprising:
causing the movable contact unit to partially project from the slider unit due to the pressing from the inserted card.
